(19) United States
(12) Patent Application Publication
(10) Pub. No.: US 2009/0041266 A1
(43) Pub. Date: Feb. 12, 2009

(54) Electrostatic loudspeaker driver

(76) Inventors: Jwin-Yen Guo, Jhubei City (TW); Liang-Pin Tai, Gueiren Shiang (TW); Shao-Ming Chang, Keelung City (TW)

Correspondence Address: ROSENBERG, KLEIN & LEE, 3458 ELLICOTT CENTER DRIVE-SUITE 101, ELLICOTT CITY, MD, 21043, US

(21) Appl. No.: 12/222,396

(22) Filed: Aug. 8, 2008

(30) Foreign Application Priority Data
Aug. 10, 2007 (TW) 096129656

(51) Int. Cl. H03G 5/16

(52) U.S. Cl. 381/98; 381/120

(57) ABSTRACT

An electrostatic loudspeaker driver includes a class-D amplifier and a demodulator circuit. The class-D amplifier is operated with a PWM signal, creating an amplified digital signal according to an input signal. A low-pass filter in the demodulator circuit filters out the PWM carrier frequency in the digital signal and retrieves an audio signal therefrom. The efficiency is improved significantly and heat sink is no longer needed.

### FIELD OF THE INVENTION

The present invention is related generally to an electrostatic loudspeaker (ESL) driver and, more particularly, to an electrostatic loudspeaker driver constructed with a class-D topology.

### BACKGROUND OF THE INVENTION

Electrostatic loudspeakers have the advantages of extremely light weight and excellent frequency response. As shown in FIG. 1, an electrostatic loudspeaker 10 includes a very thin flat plastic membrane 16 suspended between two electrodes 12 and 14. Each of the electrodes 12 and 14 is a grid or a stator, and when a pair of positive and negative voltages V+, V− with a same magnitude are applied on the electrodes 12 and 14, the membrane 16 is attracted or repelled by the electrodes 12 and 14 and thus vibrates to produce a sound wave. To generate sufficient field strength between the electrodes 12 and 14, the audio signal applied on the electrodes 12 and 14 must be of high voltage. Typical audio amplifiers can't drive two electrodes in the order of 2 KV above. Most often a transformer is used to this end. Construction of this transformer is critical, because it must provide a constant transformer ratio over the audio frequency range (20 HZ-20 KHz) and so avoids distortion. The coil inductor of the transformer should be large size if it is to be operated in the audio frequency range.

The audio amplifier was often constructed with class-A or class-AB topologies. The circuits of class-A or class-AB amplifiers are for analog designs, and a poor efficiency is realized in practical use with music signals. Conventional audio amplifiers are implemented with discrete components (such as transistors and tubes) acting as a current source. For further details about driving electrostatic loudspeakers, readers may refer to U.S. Pat. No. 4,324,950 to Strickland. For high audio power output applications, the efficiency of class-A amplifiers is lower than 25%, and that of class-AB amplifiers is lower than 60%. The power is lost in the output devices significantly, and produces heat on these output devices. Heat sinks are thus needed to prevent the output devices from being over heated, and cost and volume are both increased for the audio amplifiers.

Therefore, it is desired a high efficiency electrostatic loudspeaker driver.

### SUMMARY OF THE INVENTION

An object of the present invention is to provide a high efficiency electrostatic loudspeaker driver.

Another object of the present invention is to provide an electrostatic loudspeaker driver implemented with a class-D amplifier.

Still another object of the present invention is to shrink the coil inductor size of the transformer in an electrostatic loudspeaker driver.

Yet still another object of the present invention is to provide an electrostatic loudspeaker driver without the need of heat sinks.

According to the present invention, an electrostatic loudspeaker driver includes a class-D amplifier operated with a pulse width modulation (PWM) signal to modulate an input signal to generate an amplified digital signal, and a demodulator circuit to demodulate the digital signal to generate an output signal for driving an electrostatic loudspeaker. The demodulator circuit includes a filter to filter out the PWM carrier frequency in the digital signal and retrieve an audio signal therefrom, and a transformer to step up the voltage of the output signal.

The transformer can be alternatively disposed before the filter and in this case, the transformer operates in a high frequency range because of the PWM carrier in the digital signal. Thereby it may shrink the coil inductor size of the transformer and the whole size of the electrostatic loudspeaker driver.

The maximum efficiency of a class-D design over 90% is achieved in practice than the class-A and class-AB approaches. As a result, heat sinks are no longer needed for the output devices because no much heat is generated thereon.

### BRIEF DESCRIPTION OF THE DRAWINGS

These and other objects, features and advantages of the present invention will become apparent to those skilled in the art upon consideration of the following description of the preferred embodiments of the present invention taken in conjunction with the accompanying drawings, in which:

FIG. 1 shows a structure of an electrostatic loudspeaker;

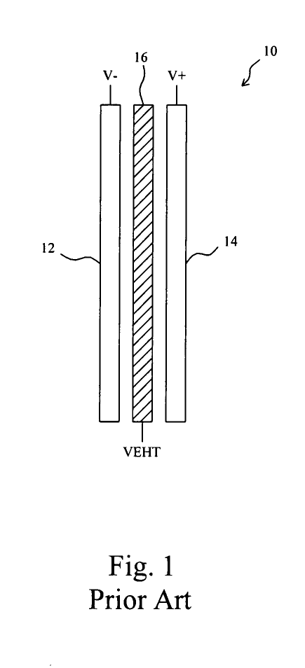

FIG. 2 shows a first embodiment according to the present invention;

FIG. 3 shows a second embodiment according to the present invention;

FIG. 4 shows a third embodiment according to the present invention;

FIG. 5 shows a fourth embodiment according to the present invention;

FIG. 6 shows a fifth embodiment according to the present invention; and

FIG. 7 shows a sixth embodiment according to the present invention.

### DETAIL DESCRIPTION OF THE INVENTION

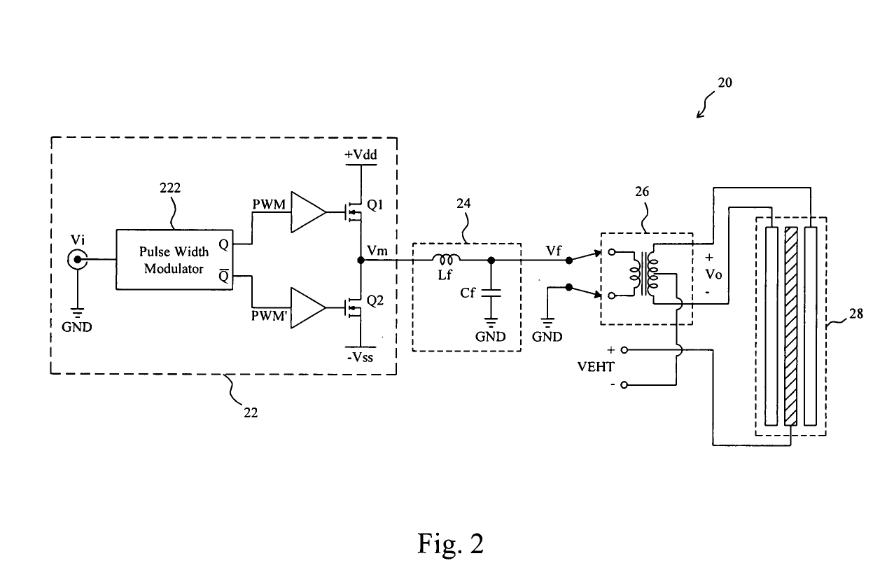

FIG. 2 shows a first embodiment according to the present invention. In an electrostatic loudspeaker driver 20, a half-bridge class-D amplifier 22 has an input to receive an input signal Vi and generates an amplified digital signal Vm accordingly, and a demodulator circuit which includes an L-C demodulator filter 24 and a step-up transformer 26 retrieves an audio signal from the digital signal Vm and produces an output signal Vo for driving an electrostatic loudspeaker 28. In the half-bridge class-D amplifier 22, two transistors Q1 and Q2 are serially connected between two power nodes +Vdd and −Vss, and a pulse width modulator 222 modulates the input signal Vi to generate pulse width modulation signals PWM and PWM′ to switch the transistors Q1 and Q2 respectively, so as to generate the digital signal Vm. A class-D amplifier is basically a switching amplifier. In this kind of amplifiers all power devices are operated in on/off state with a PWM signal, thereby reducing the power losses in the output devices significantly. The main advantage of this kind of amplifiers is the high efficiency and use of heat sink unnecessary. The best efficiency of a class-D amplifier is over 90%. Therefore, the electrostatic loudspeaker driver 20 has a much better efficiency than those of conventional electrostatic loudspeaker drivers. The output devices generally refer to the components on the paths from the power node +Vdd to the output Vo and from the output Vo to the power node −Vss. In the demodulator circuit, the L-C demodulator filter 24 is a low-pass filter for filtering out the PWM carrier frequency in the digital signal Vm and thus retrieves an audio signal Vf therefrom, and the step-up transformer 26 transforms the audio signal Vf into the output signal Vo of higher voltage. In this embodiment, the frequency range of the audio signal Vf is from 20 Hz to 20 kHz, and thus the transformer 26 operates in the audio frequency range of 20 Hz-20 kHz. In the whole audio frequency range, the transformer 26 provides a constant transformer ratio to prevent distortion.

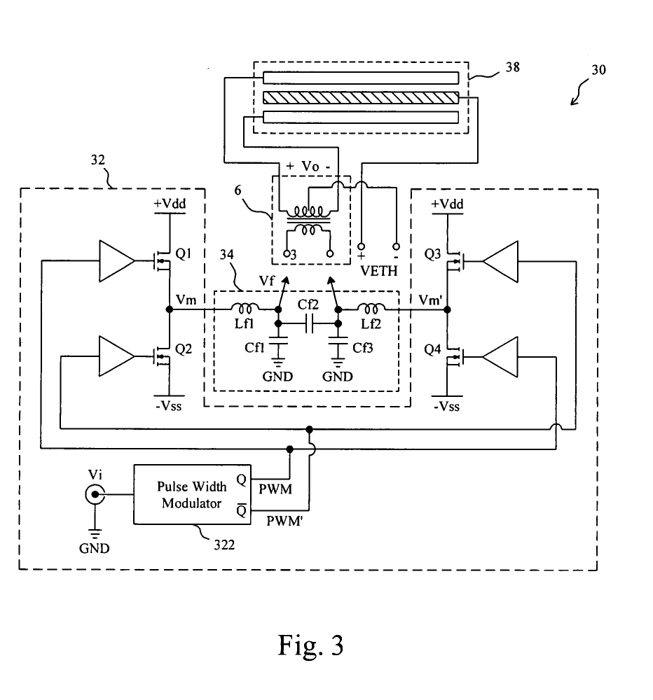

FIG. 3 shows a second embodiment according to the present invention. In an electrostatic loudspeaker driver 30, a full-bridge class-D amplifier 32 has an input to receive an input signal Vi and generates two digital signals Vm and Vm′ accordingly, and a demodulator circuit which includes an L-C demodulator filter 34 and a step-up transformer 36 demodulates the digital signals Vm and Vm′ to generate an output signal Vo for driving an electrostatic loudspeaker 38. In the full-bridge class-D amplifier 32, four transistors Q1, Q2, Q3 and Q4 are configured with a full-bridge topology between two power nodes +Vdd and −Vss, and a pulse width modulator 322 modulates the input signal Vi to generate pulse width modulation signals PWM and PWM′ to switch the transistors Q1, Q2, Q3 and Q4 to generate the digital signals Vm and Vm′. In the demodulator circuit, the L-C demodulator filter 34 is a low-pass filter for filtering out the PWM carrier frequency in the digital signals Vm and Vm′ to retrieve an audio signal Vf having a frequency ranged from 20 Hz to 20 kHz, and the transformer 36 transforms the audio signal Vf into the output signal Vo of higher voltage. In this embodiment, the frequency range of the audio signal Vf is from 20 Hz to 20 kHz, and thus the transformer 36 operates in the audio frequency range of 20 Hz-20 kHz. In the whole audio frequency range, the transformer 36 provides a constant transformer ratio to prevent distortion.

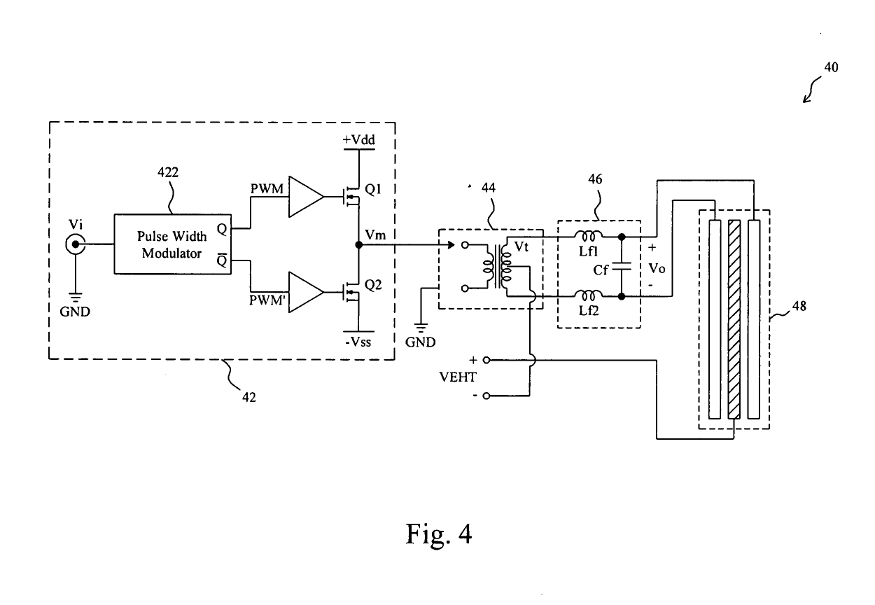

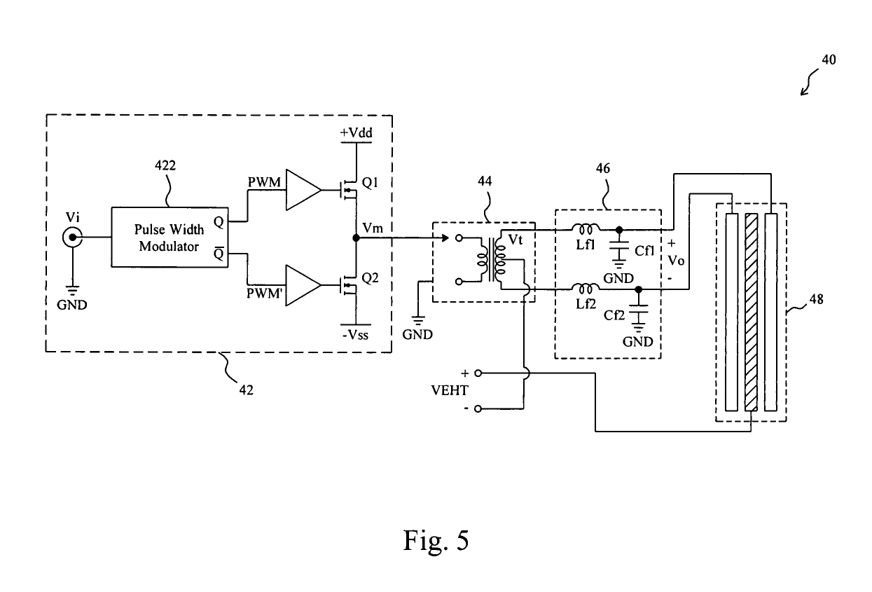

FIG. 4 shows a third embodiment according to the present invention. In an electrostatic loudspeaker driver 40, a half-bridge class-D amplifier 42 has an input to receive an input signal Vi and generates a digital signal Vm accordingly, and a demodulator circuit which includes a step-up transformer 44 and an L-C demodulator filter 46 demodulates the digital signal Vm to generate an output signal Vo for driving an electrostatic loudspeaker 48. In the half-bridge class-D amplifier 42, two transistors Q1 and Q2 are serially connected between two power nodes +Vdd and −Vss, and a pulse width modulator 422 modulates the input signal Vi to generate pulse width modulation signals PWM and PWM′ to switch the transistors Q1 and Q2 respectively, so as to generate the digital signal Vm. In the demodulator circuit, the transformer 44 transforms the digital signal Vm into a higher voltage signal Vt, and the L-C demodulator filter 46 filters out the PWM carrier frequency in the signal Vt to retrieve an audio signal as the output signal Vo. The L-C demodulator filter 46 includes two inductors Lf1 and Lf2 connected to two output terminals of the transformer 44 respectively, and a capacitor Cf is connected between the other terminals of the inductors Lf1 and Lf2. In this embodiment, the transformer 44 is disposed before the L-C demodulator filter 46 and thus directly driven by the digital signal Vm from the class-D amplifier 42. Since the digital signal Vm includes the PWM carrier, the frequency thereof is higher than 250 kHz and therefore, the transformer 44 operates in the frequency range of higher than 250 kHz. The coil inductor size of the transformer 44 can be smaller because the inductance needed for high-frequency response is smaller than that for low-frequency response. In the whole frequency range of the digital signal Vm, the transformer 44 provides a constant transformer ratio to prevent distortion. FIG. 5 shows another embodiment which uses an L-C demodulator filter 46 having alternative configuration. In this L-C demodulator filter 46, two inductors Lf1 and Lf2 are connected to two output terminals of the transformer 44 respectively, and two capacitors Cf1 and Cf2 are connected between the other terminals of the inductors Lf1 and Lf2 and ground GND respectively.

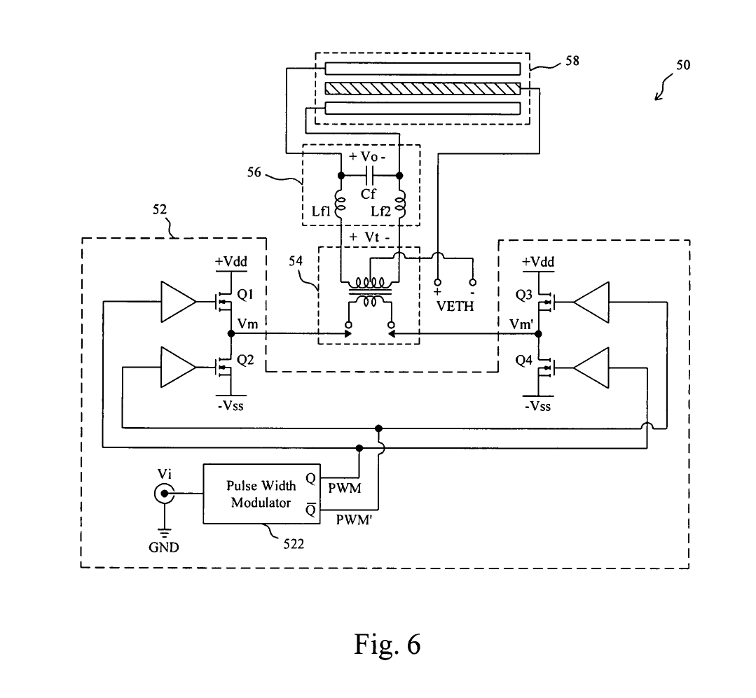

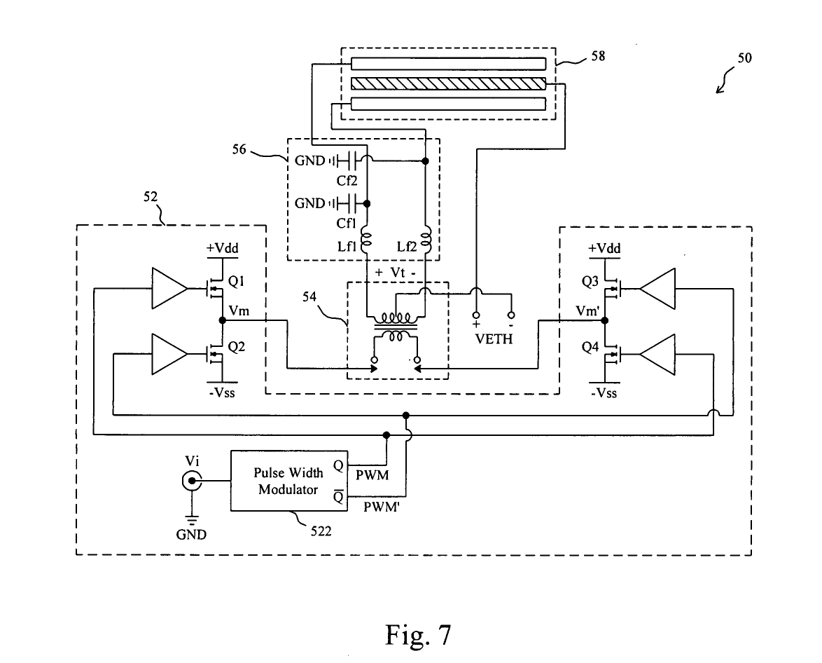

In the electrostatic loudspeaker driver 50 shown in FIG. 6, a full-bridge class-D amplifier 52 has an input to receive an input signal Vi and generates two digital signals Vm and Vm′, and a demodulator circuit which includes a step-up transformer 54 and an L-C demodulator filter 56 generates an output signal Vo for driving an electrostatic loudspeaker 58 according to the digital signals Vm and Vm′. In the class-D amplifier 52, a pulse width modulator 522 generates pulse width modulation signals PWM and PWM′ according to the input signal Vi, to switch the transistors Q1, Q2, Q3 and Q4 to generate the digital signals Vm and Vm′. In the demodulator circuit, the transformer 54 has two input terminals to receive the digital signals Vm and Vm′ respectively, and transforms them into a higher voltage signal Vt. Since the digital signals Vm and Vm′ include the PWM carrier, the transformer 54 operates in the frequency range of higher than 250 kHz. Therefore, the coil inductor size of the transformer 54 can be smaller. In the whole frequency range of the digital signals Vm and Vm′, the transformer 54 provides a constant transformer ratio to prevent distortion. The L-C demodulator filter 56 includes two inductors Lf1 and Lf2 connected to two output terminals of the transformer 54 respectively, and a capacitor Cf connected between the other terminals of the inductors Lf1 and Lf2. The L-C demodulator filter 56 is for filtering out the PWM carrier frequency in the signal Vt to retrieve an audio signal therefrom, as the output signal Vo. FIG. 7 shows another embodiment which uses an L-C demodulator filter 56 having alternative configuration. In this L-C demodulator filter 56, two inductors Lf1 and Lf2 are connected to two output terminals of the transformer 54 respectively, and two capacitors Cf1 and Cf2 are connected between the other terminals of the inductors Lf1 and Lf2 and ground GND respectively.

While the present invention has been described in conjunction with preferred embodiments thereof, it is evident that many alternatives, modifications and variations will be apparent to those skilled in the art. Accordingly, it is intended to embrace all such alternatives, modifications and variations that fall within the spirit and scope thereof as set forth in the appended claims.

What is claimed is:

1. An electrostatic loudspeaker driver comprising:
a class-D amplifier having an input to receive an input signal; and
a demodulator circuit connected to the class-D amplifier;
wherein the class-D amplifier generates a digital signal and the demodulator circuit generates an output signal from the digital signal.

2. The electrostatic loudspeaker driver of claim 1, wherein the class-D amplifier comprises a half-bridge topology.

3. The electrostatic loudspeaker driver of claim 1, wherein the class-D amplifier comprises:
a pair of switches serially connected between two power nodes; and
a pulse width modulator connected to the pair of switches;
wherein the pulse width modulator modulates the input signal to generate a pulse width modulation signal to switch the pair of switches, so as to generate the digital signal.

4. The electrostatic loudspeaker driver of claim 1, wherein the class-D amplifier comprises a full-bridge topology.

5. The electrostatic loudspeaker driver of claim 1, wherein the class-D amplifier comprises:
a first pair of switches serially connected between two power nodes;
a second pair of switches serially connected between the two power nodes; and
a pulse width modulator connected to the first and second pairs of switches;
wherein the pulse width modulator modulates the input signal to generate a pulse width modulation signal to switch the first and second pairs of switches, so as to generate the digital signal.

6. The electrostatic loudspeaker driver of claim 1, wherein the demodulator circuit comprises:
a filter connected to the class-D amplifier; and
a transformer connected to the filter;
wherein the filter filters out carrier frequency in the digital signal and retrieves an audio signal, and the transformer transforms the audio signal into the output signal.

7. The electrostatic loudspeaker driver of claim 6, wherein the filter comprises a low-pass filter.

8. The electrostatic loudspeaker driver of claim 6, wherein the filter comprises an L-C demodulator filter.

9. The electrostatic loudspeaker driver of claim 6, wherein the transformer operates in a frequency range of 20 Hz to 20 kHz.

10. The electrostatic loudspeaker driver of claim 6, wherein the transformer comprises a step-up transformer.

11. The electrostatic loudspeaker driver of claim 1, wherein the demodulator circuit comprises:
a transformer connected to the class-D amplifier; and
a filter connected to the transformer;
wherein the transformer transforms the digital signal to be of higher voltage and the filter retrieves an audio signal therefrom as the output signal.

12. The electrostatic loudspeaker driver of claim 11, wherein the transformer operates in a frequency range of higher than 250 kHz.

13. The electrostatic loudspeaker driver of claim 11, wherein the transformer comprises a step-up transformer.

14. The electrostatic loudspeaker driver of claim 11, wherein the filter comprises a low-pass filter.

15. The electrostatic loudspeaker driver of claim 11, wherein the filter comprises an L-C demodulator filter.
